(19) United States
(12) Patent Application Publication
(10) Pub. No.: US 2025/0004035 A1
(43) Pub. Date: Jan. 2, 2025

(54) ALGORITHM FOR ASSESSMENT OF FORWARD BIASED JUNCTIONS DETECTED DURING CIRCUIT OPERATION

(71) Applicant: Intel Corporation, Santa Clara, CA (US)

(72) Inventors: Krzysztof DOMANSKI, Neubiberg (DE); Manhar MUDDU, Vijayawada (IN)

(21) Appl. No.: 18/343,763

(22) Filed: Jun. 29, 2023

(51) Int. Cl. G01R 31/26

(52) U.S. Cl. CPC G01R 31/2621

(57) ABSTRACT

A non-transitory computer readable medium is provided. The non-transitory computer readable medium having instructions stored therein that when executed by a processor cause the processor to: receive current information of a semiconductor device, calculate an absolute current value of the semiconductor device from the current information and compare the absolute current value with a first threshold; receive information regarding a duration of a forward bias of the semiconductor device and compare the duration with a second threshold if the absolute current value is more than the first threshold; perform a layout review of tap spacing of selected semiconductor device components; and output safe operation area (SOA) information indicating a forward bias junction result based on the absolute current value, the duration of forward bias and the layout review.

### TECHNICAL FIELD

This disclosure generally relates to an algorithm for assessment of forward biased junctions detected during circuit operation.

### BACKGROUND

Forward biased junctions (e.g., V>0.33V in forward direction) are generally prohibited in operation of circuits fabricated transistors such as field effect transistors (FET) and/or planar technologies because of reliability risks. An excessively forward biased junction can drive high current and cause melting of the metallization or even trigger latch-up in operation. An integrated circuit (IC) with inherent latch-up weakness can cause full mask redesign. When detected in field, even costly field returns of ramped product might be required.

To prevent forward-biased junction in circuit, a Safe Operating Area (SOA) check was developed as a tool in the design system. That check assesses the electrical simulations of design in respect to forward biased junctions and flags the violations of >0.33V junction-forward-bias in the design. In a typical design, however, dozens of thousands of forward biased junctions are detected. Previously, all those violation had to be assessed manually which is time-consuming. In many cases, the violations count is typically too big to review all cases and some real violations might get overlooked if thorough review was not done. To dispose SOA violations, schematics must be reviewed, together with a voltage/current waveform. For special cases also a layout inspection is needed which requires a long period of time. Hence, previous manual assessment of SOA was, therefore, based on judgment calls. Error disposition was done taking into account selected feature of violation only. For example, the disposition was decided based on the cell name where the junction forward bias was flagged in SOA. Those manual reviews were flawed by risk and caused uncertainty of hardware performance.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows a schematic diagram illustrating a computing device;

FIG. 2 illustrates a flow diagram for a method checking for SOA violations;

FIG. 3 shows an exemplary algorithm for checking for SOA violations; and

FIG. 4 shows a table showing results of an exemplary SOA violation check.

### DESCRIPTION

The following detailed description refers to the accompanying drawings that show, by way of illustration, specific details and aspects in which the invention may be practiced.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The words “plural” and “multiple” in the description and in the claims expressly refer to a quantity greater than one. Accordingly, any phrases explicitly invoking the aforementioned words (e.g., “a plurality of (objects)”, “multiple (objects)”) referring to a quantity of objects expressly refer to more than one of the said objects. The terms “group (of)”, “set (of)”, “collection (of)”, “series (of)”, “sequence (of)”, “grouping (of)”, etc., and the like in the description and in the claims, if any, refer to a quantity equal to or greater than one, i.e. one or more.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art. Any type of information, as described herein, may be handled for example via one or more processors in a suitable way, e.g. as data.

The terms “processor” or “controller” as, for example, used herein may be understood as any kind of entity that allows handling data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” detailed herein may be understood to include any suitable type of memory or memory device, e.g., a hard disk drive (HDD), a solid-state drive (SSD), a flash memory, etc.

The term “module” detailed herein refers to, or forms part of, or includes an Application Specific Integrated Circuit (ASIC); an electronic circuit; a combinational logic circuit; a field programmable gate array (FPGA); a processor (shared, dedicated, or group) that executes code; other suitable hardware components that provide the described functionality; or a combination of some or all of the above, such as in a system-on-chip. The term module may include memory (shared, dedicated, or group) that stores code executed by the processor.

A processor, controller, and/or circuit detailed herein may be implemented in software, hardware, and/or as a hybrid implementation including software and hardware.

The term “system” (e.g., an artificial intelligence system, a machine learning system, a computing system, etc.) detailed herein may be understood as a set of interacting elements, of which the elements can be, by way of example and not of limitation, one or more mechanical components, one or more electrical components, one or more instructions (e.g., encoded in storage media), and/or one or more processors, and the like.

The term “semiconductor device” as used herein refers to both the singular and plural form of the words, and accordingly can refer to both a single semiconductor device and multiple semiconductor devices.

An advantage of the present disclosure may include improved or reduced cross talk by application of a dielectric layer.

An advantage of the present disclosure may include controlled EMI through application of an EMI absorber.

These and other aforementioned advantages and features of the aspects herein disclosed will be apparent through reference to the following description and the accompanying drawings. Furthermore, it is to be understood that the features of the various aspects described herein are not mutually exclusive and can exist in various combinations and permutations.

The present disclosure generally relates to a non-transitory computer readable medium. The non-transitory computer readable medium may include instructions stored therein that when executed by a processor cause the processor to: measure an absolute current value of a semiconductor device and compare the absolute current value with a first threshold; measure a duration of forward bias of the semiconductor device and compare the duration with a second threshold if the absolute current value is more than the first threshold; perform a layout review of tap spacing of selected semiconductor device components; and output safe operation area (SOA) information indicating a forward bias junction result based on the absolute current value, the duration of forward bias and the layout review.

The present disclosure generally relates to a computing device. The computing device may include a semiconductor device. The computing device may include a processor and a non-transitory computer readable medium. The non-transitory computer readable medium may include instructions stored therein that when executed by a processor cause the processor to: measure an absolute current value of a semiconductor device and compare the absolute current value with a first threshold; measure a duration of forward bias of the semiconductor device and compare the duration with a second threshold if the absolute current value is more than the first threshold; perform a layout review of tap spacing of selected semiconductor device components; and output safe operation area (SOA) information indicating a forward bias junction result based on the absolute current value, the duration of forward bias and the layout review.

To more readily understand and put into practical effect, the present device, computing device, method, and other particular aspects will now be described by way of examples and not limitations, and with reference to the figures. For the sake of brevity, duplicate descriptions of features and properties may be omitted.

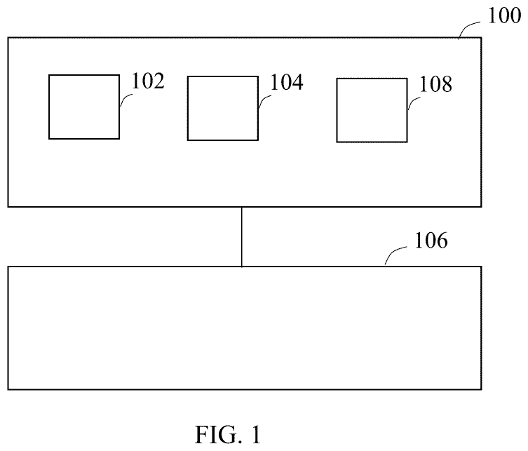

FIG. 1 shows a schematic diagram illustrating a computing device 100.

In an aspect, the computing device 100 may include a processor 102. The computing device may include an input/output module 104 for communication with a semiconductor device 106. The computing device may also include a non-transitory computer readable medium which may be a part of the processor 102.

In an aspect, the non-transitory computer readable medium may include instructions stored therein that when executed by the processor 102 cause the processor 102 to output safe operation area (SOA) information regarding forward bias junction result of the semiconductor device 106.

In an aspect, the processor 102 may receive current information of a semiconductor device 106 from a measuring device 108 connected to the semiconductor device 106. The processor may calculate an absolute current value of the semiconductor device and compare the absolute current value with a first threshold. The first threshold is a predetermined value and may be for example 1 pA. In an aspect, if the absolute current value is less than the first threshold, the processor may determine that the forward bias junction result is negative. If the absolute current value is more than the first threshold, the processor 102 may measure a duration of forward bias of the semiconductor device and compare the duration with a second threshold.

In an aspect, the processor 102 is configured to receive information regarding a duration of a forward bias of the semiconductor device from the measuring device 108. The processor 102 is configured to compare the duration of forward bias by measuring a product of a bulk current time duration and/or a gate current time duration. In an aspect, the second threshold is a predetermined value and may be for example 100 nA*nsec.

In an aspect, the processor 102 may be configured to perform a layout review of tap spacing of selected semiconductor device components. The layout review of the tap spacing of selected semiconductor device components is performed if the product of a bulk current time duration and/or the gate current time duration is more than the second threshold.

In an aspect, performing the layout review of tap spacing comprises measuring a tap spacing information between a drain or source to a bulk contact. In an aspect, the processor 102 is further configured to measure a ratio N of a predetermined maximum tap spacing divided by the measured tap spacing information. In an aspect, the processor 102 is further configured to compare the duration of forward bias with the ratio N and the second threshold value.

In an aspect, the processor 102 is configured to output safe operation area (SOA) information indicating a forward bias junction result based on the absolute current value, the duration of forward bias and the layout review. In an aspect, the forward bias junction results include information regarding which forward bias junction requires manual checking.

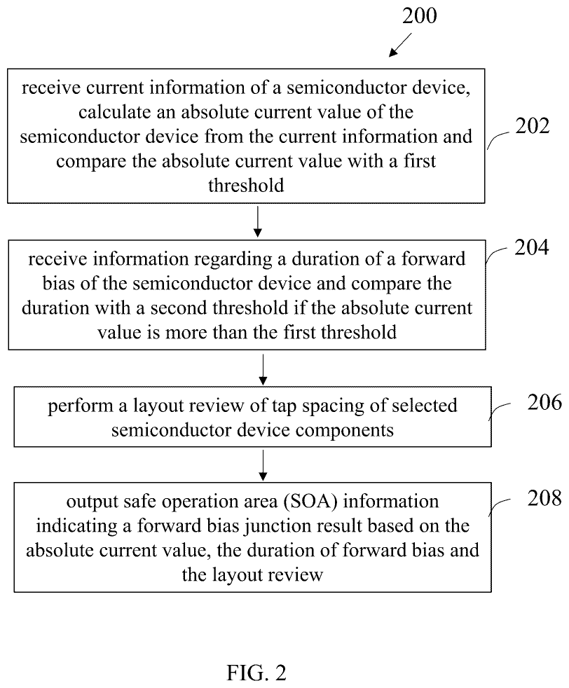

In an aspect, the semiconductor device 106 may be a field effect transistor, finFET transistor, bipolar transistor, bipolar diode, parasitic body diode, u-well/p-well, u+/p-well, p+/u-well or involving parasitic diodes in triple well process option. FIG. 2 illustrates a flow diagram for a method checking for SOA violations.

According to various aspects, in step 202, current information of a semiconductor device is received. An absolute current value of the semiconductor device from the current information is calculated and the absolute current value is compared with a first threshold.

According to various aspects, in step 204, information regarding a duration of a forward bias of the semiconductor device is received. If the absolute current value is more than the first threshold, the duration of forward bias of the semiconductor device is compared with a second threshold.

According to various aspects, in step 206, a layout review of tap spacing of selected semiconductor device components is performed. The layout review may be automated or manual.

According to various aspects, in step 208, safe operation area (SOA) information which indicates a forward bias junction result based on the absolute current value, the duration of forward bias and the layout review is outputted.

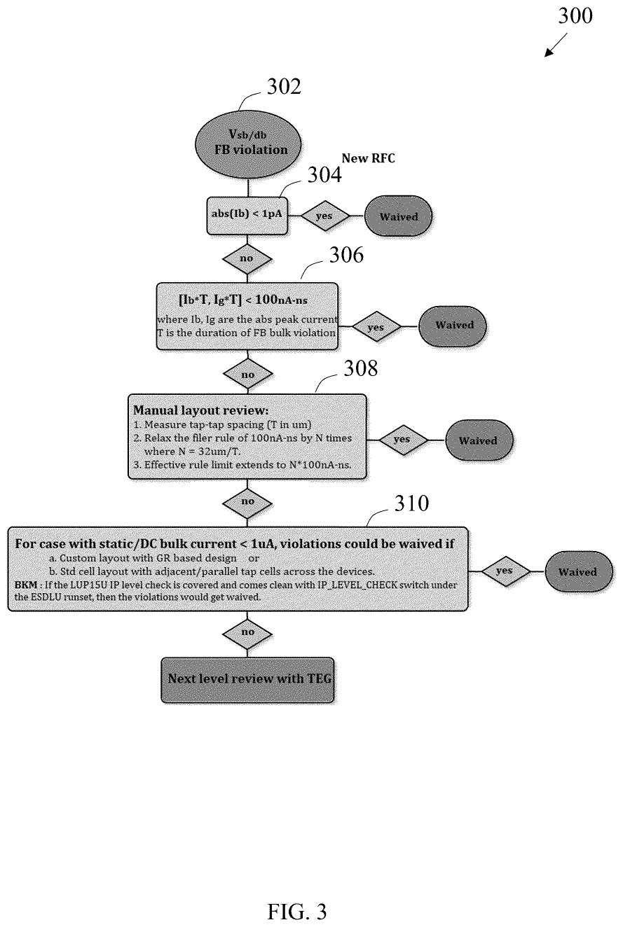

FIG. 3 shows an exemplary algorithm 300 for checking for SOA violations 302.

At step 304, if peak absolute value of substrate current: abs (lb)<1 pA then the processor outputs a blanket waiver. If abs (lb)>1 pA, then the processor follows a filter mechanism. Step 304 describes bulk current threshold <1 pA at which the >0.33V forward-bias violations are waived without further evaluation. Usually, those violations occur due to charging of high ohmic nodes via gate in e.g. several nch and/or pch devices is stacked, where source and/or drain of some devices is made floating by switched-off upper and lower device in series-stack (e.g. in AND logic). An alternative aspect can contain conditions for thresholds of drain and/or source and/or gate current.

At step 306, the processor measures the product of Ib*T and/or Ig*T, where T is the duration of bulk violation per forward bias event. Optionally, the product of bulk current Ib times duration T (Ib*T) and/or gate current Ig times duration T (Ig*T) is calculated. The products from Ib*T or Ig*T are checked if smaller than 100 nA*nsec. The 100 nA times nanosecond is an arbitrary threshold for waiver of violations based on electrical parameters only. In alternative aspect a different value can be used or different thresholds can be used for Ib*T and/or Ig*T and/or Idrain*T and/or Isource*T. In case that the current times duration >100 nA*nsec, automated filtering will flag violation for manual review of tap-spacing. If Ib*T & Ig*T<100 nA*nsec, then the violations are waived. If not, then follow step 308.

At step 308, based on the tap-tap spacing using manual layout review:

Let tap-tap spacing value be T um (in this example T=32 um).

The new filtering value relaxes to N times 100 nA*nsec, where N=32 um/T um.

Step 308 defines the maximal tap-spacing (spacing drain/source to bulk contact) T in given technology, in alternative aspect different number can be used. Alternatively different numbers can be used for different device class and/or dual/triple well process option, and/or even nch and/or pch, or any combination of above listed. The tap spacing for assessed device has to be measured, a ratio N equals maximum tap spacing of 32 um divided by measured tap-spacing T in device that is assessed. The product of maximal current times duration is calculated for base and/or gate (Ib*T and/or Ig*T). If the product is smaller than product of N times 100 nA, then the violation can be waived. The motivation for waiver is that with reduced tap spacing linearly the resistance R of device to tap reduces, with linear reduction of resistance the voltage drop U in well reduces as given by Ohmic law U=I*R. Concluding, the same current creates less voltage drop at body diode of the device. It should be noted that the well resistance drain/source to bulk contact is not extracted in typical design systems, an alternative aspect with flow for well-resistance extraction is a part of the invention.

If Ib*T<N*100 nA′nsec, then the violations are waived. If not, redesign is needed and step 310 is followed.

Alternatively, if Ig*T<N*100 nA*nsec, then the violations are waived.

In an aspect, the processor calculates a product of the forward bias Ib*T and/or Ig*T times the ratio N.

In an aspect, a third threshold may be Ib*T*N and/or Ig*T*N. The processor may compare the forward bias Ib*T and/or Ig*T with the third threshold of be Ib*T*N and/or Ig*T*N.

At step 310, for cases which have save layout for latch-up, (a,b) are the layout suggestions for manual waivers for bulk current <1 uA DC, implying either a custom layout with GR based design, or a standard cell layout with adjacent/parallel tap cells across the devices.

In step 310, the SOA violation that indicate current <1 uA are assessed for layout modification. A first latch-up guard-ring should be placed around the device. If SOA violations detected in standard-cell area, then the device must be surrounded with strap-cells, and parasitic thyristors have to be decoupled in adjacent well tracks (e.g. nch removed in adjacent to flagged pch, or pch removed from surrounding of flagged nch). All violations that indicate bulk current >1 uA are assessed for circuit redesign and reduction of bulk current. The 1 uAmp threshold is listed in preferred aspect, can vary for alternative aspects.

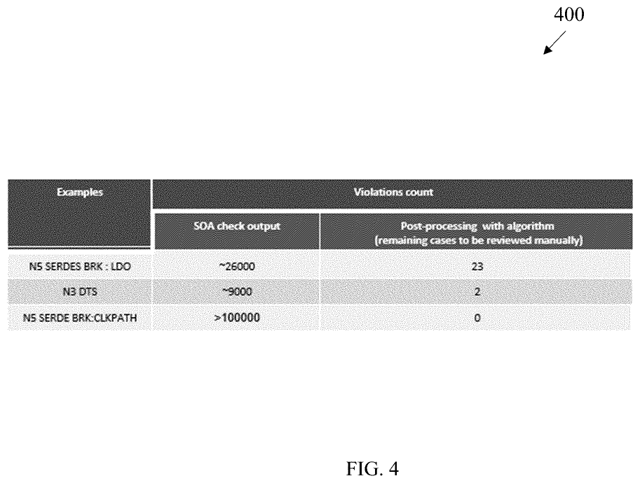

FIG. 4 shows a table 400 showing results of an exemplary SOA violation check.

As shown in table 400, after using the techniques disclosed herein, only few real violations remain for manual review. Advantageously, appropriate treatment of SOA violations removes latch-up and reliability risk from ICs.

Also, there is significant reduction of effort for completion of SOA checks. The claimed algorithm enables quick and automated dispositioning of dummy violations of junction forward bias in SOA check. Effort can be reduced to less than 1 hour of review with only few borderline cases flagged by algorithm for manual review.

### EXAMPLES

The examples set forth herein are illustrative and not exhaustive.

Example 1 is a non-transitory computer readable medium having instructions stored therein that when executed by a processor cause the processor to: receive current information of a semiconductor device, calculate an absolute current value of the semiconductor device from the current information and compare the absolute current value with a first threshold; receive information regarding a duration of a forward bias of the semiconductor device and compare the duration with a second threshold if the absolute current value is more than the first threshold; perform a layout review of tap spacing of selected semiconductor device components; and output safe operation area (SOA) information indicating a forward bias junction result based on the absolute current value, the duration of forward bias and the layout review.

Example 2 may include the non-transitory computer readable medium of example 1 and/or any other example disclosed herein, in which the processor is configured to measure the duration of the forward bias by calculating a bulk current time duration and/or a gate current time duration.

Example 3 may include the non-transitory computer readable medium of example 1 and/or any other example disclosed herein, in which the first threshold is 1 pA.

Example 4 may include the non-transitory computer readable medium of example 2 and/or any other example disclosed herein, in which the layout review of the tap spacing of selected semiconductor device components is performed if the bulk current time duration or the gate current time duration is more than the second threshold.

Example 5 may include the non-transitory computer readable medium of example 4 and/or any other example disclosed herein, in which the second threshold is 100 nA*nsec.

Example 6 may include the non-transitory computer readable medium of example 1 and/or any other example disclosed herein, in which performing the layout review of tap spacing comprises measuring a tap spacing information between a drain or source to a bulk contact.

Example 7 may include the non-transitory computer readable medium of example 6 and/or any other example disclosed herein, in which the processor is further configured to measure a ratio N of a predetermined maximum tap spacing divided by the measured tap spacing information.

Example 8 may include the non-transitory computer readable medium of example 7 and/or any other example disclosed herein, in which the processor is further configured to compare the duration of forward bias with the ratio N and the second threshold.

Example 9 may include the non-transitory computer readable medium of example 1 and/or any other example disclosed herein, in which the forward bias junction results comprise information regarding which forward bias junction requires manual checking.

Example 10 may include the non-transitory computer readable medium of example 1 and/or any other example disclosed herein, in which the semiconductor device is a field effect transistor.

Example 11 is a computing device having a semiconductor device, a processor and a non-transitory computer readable medium having instructions stored therein that when executed by a processor cause the processor to: receive current information of the semiconductor device, calculate an absolute current value of the semiconductor device from the current information and compare the absolute current value with a first threshold; receive information regarding a duration of a forward bias of the semiconductor device and compare the duration with a second threshold if the absolute current value is more than the first threshold; perform a layout review of tap spacing of selected semiconductor device components; and output safe operation area (SOA) information indicating a forward bias junction result based on the absolute current value, the duration of forward bias and the layout review.

Example 12 may include the computing device of example 11 and/or any other example disclosed herein, in which the processor is configured to measure the duration of the forward bias by calculating a bulk current time duration and/or a gate current time duration.

Example 13 may include the computing device of example 11 and/or any other example disclosed herein, in which wherein the first threshold is 1 pA.

Example 14 may include the computing device of example 12 and/or any other example disclosed herein, in which the layout review of the tap spacing of selected semiconductor device components is performed if the bulk current time duration or the gate current time duration is more than the second threshold.

Example 15 may include the computing device of example 14 and/or any other example disclosed herein, in which the second threshold is 100 nA*nsec.

Example 16 may include the computing device of example 11 and/or any other example disclosed herein, in which performing the layout review of tap spacing comprises measuring a tap spacing information between a drain or source to a bulk contact.

Example 17 may include the computing device of example 16 and/or any other example disclosed herein, in which the processor is further configured to measure a ratio N of a predetermined maximum tap spacing divided by the measured tap spacing information.

Example 18 may include the computing device of example 17 and/or any other example disclosed herein, in which the processor is further configured to compare the duration of forward bias with the ratio N and the second threshold.

Example 19 may include the computing device of example 11 and/or any other example disclosed herein, in which the forward bias junction results comprise information regarding which forward bias junction requires manual checking.

Example 20 may include the computing device of example 11 and/or any other example disclosed herein, in which the semiconductor device is a field effect transistor.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A non-transitory computer readable medium, comprising instructions stored therein that when executed by a processor cause the processor to:
receive current information of a semiconductor device, calculate an absolute current value of the semiconductor device from the current information and compare the absolute current value with a first threshold;
receive information regarding a duration of a forward bias of the semiconductor device and compare the duration with a second threshold if the absolute current value is more than the first threshold;
perform a layout review of a tap spacing of selected semiconductor device components; and
output safe operation area (SOA) information indicating a forward bias junction result based on the absolute current value, the duration of the forward bias and the layout review.

2. The non-transitory computer readable medium of claim 1, wherein the processor is configured to measure the duration of the forward bias by calculating a bulk current time duration and/or a gate current time duration.

3. The non-transitory computer readable medium of claim 1, wherein the first threshold is 1 pA.

4. The non-transitory computer readable medium of claim 2, wherein the layout review of the tap spacing of selected semiconductor device components is performed if the bulk current time duration or the gate current time duration is more than the second threshold.

5. The non-transitory computer readable medium of claim 4, wherein the second threshold is 100 nA*ns.

6. The non-transitory computer readable medium of claim 2, wherein performing the layout review of the tap spacing comprises measuring a tap spacing information between a drain or source to a bulk contact to obtain a measured tap spacing information.

7. The non-transitory computer readable medium of claim 6, wherein the processor is further configured to measure a ratio N of a predetermined maximum tap spacing divided by the measured tap spacing information.

8. The non-transitory computer readable medium of claim 7, wherein the processor is further configured to compare the duration of the forward bias with the ratio N and the second threshold.

9. The non-transitory computer readable medium of claim 1, wherein the forward bias junction result comprise information regarding which the forward bias junction requires manual checking.

10. The non-transitory computer readable medium of claim 1, wherein the semiconductor device is a field effect transistor.

11. A computing device comprising:
a semiconductor device;
a processor; and
a non-transitory computer readable medium comprising instructions stored therein that when executed by the processor cause the processor to:
receive current information of the semiconductor device, calculate an absolute current value of the semiconductor device from the current information and compare the absolute current value with a first threshold;
receive information regarding a duration of a forward bias of the semiconductor device and compare the duration with a second threshold if the absolute current value is more than the first threshold;
perform a layout review of a tap spacing of selected semiconductor device components; and
output safe operation area (SOA) information indicating a forward bias junction result based on the absolute current value, the duration of the forward bias and the layout review.

12. The computing device of claim 11, wherein the processor is configured to measure the duration of the forward bias by calculating a bulk current time duration and/or a gate current time duration.

13. The computing device of claim 11, wherein the first threshold is 1 pA.

14. The computing device of claim 12, wherein the layout review of the tap spacing of selected semiconductor device components is performed if the bulk current time duration or the gate current time duration is more than the second threshold.

15. The computing device of claim 14, wherein the second threshold is 100 nA*ns.

16. The computing device of claim 11, wherein performing the layout review of the tap spacing comprises measuring a tap spacing information between a drain or source to a bulk contact to obtain a measured tap spacing information.

17. The computing device of claim 16, wherein the processor is further configured to measure a ratio N of a predetermined maximum tap spacing divided by the measured tap spacing information.

18. The computing device of claim 17, wherein the processor is further configured to compare the duration of the forward bias with the ratio N and the second threshold.

19. The computing device of claim 11, wherein the forward bias junction result comprises information regarding which the forward bias junction requires manual checking.

20. The computing device of claim 11, wherein the semiconductor device is a field effect transistor.
